(19) United States
(12) Patent Application Publication
(10) Pub. No.: US 2008/0150608 A1
(43) Pub. Date: Jun. 26, 2008

(54) Integrated semiconductor circuit

(76) Inventor: Marco Schreiter, Dresden (DE)

Correspondence Address: Muncy, Geissler, Olds & Lowe, PLLC, P.O. BOX 1364, FAIRFAX, VA, 22038-1364, US

(21) Appl. No.: 11/953,739

(22) Filed: Dec. 10, 2007

Related U.S. Application Data
(60) Provisional application No. 60/874,004, filed on Dec. 11, 2006.

(30) Foreign Application Priority Data
Dec. 9, 2006 (DE) DE 102006058169

(51) Int. Cl. H03K 17/687

(52) U.S. Cl. 327/434

(57) ABSTRACT

An integrated semiconductor circuit is provided with a connection node, which is provided for decoupling electric signals, and with a plurality of electric signal lines, which are formed to provide in-circuit signals, particularly test signals, to the connection node. An in-circuit release device, which can be switched between a release state to release the signal line and a blocking state to block the signal line, is looped in the signal lines. The release device has switching means, which are formed in such a way that the blocking state for the signal line is assured irrespective of a signal or test signal electric potential applied to the signal line. The release device furthermore, has control means, which are provided for controlling the switching means. The control means can be formed in such a way that a cross-current-free release of the specific signal line is assured.

This nonprovisional application claims priority to German Patent Application No. DE 102006058169, which was filed in Germany on Dec. 10, 2006, and to U.S. Provisional Application No. 60/874,004, which was filed on Dec. 11, 2006, and which are both herein incorporated by reference.

### BACKGROUND OF THE INVENTION

1. Field of the Invention

The present invention relates to an integrated semiconductor circuit with a connection node, which is provided for decoupling electric signals, and with a plurality of electric signal lines, which are formed to provide in-circuit signals, particularly test signals, to the connection node. An in-circuit release device, which can be switched between a release state to release the signal line and a blocking state to block the signal line, is looped in the signal lines in each case. The release device has a switch, which is formed in such a way that the blocking state for the signal line is assured irrespective of a signal or test signal electric potential applied to the signal line. The release device, furthermore, has a control provided for controlling the switch.

2. Description of the Background Art

Conventional integrated semiconductor circuits have a plurality of electronic components, such as transistors, resistors, capacitors, etc., which are realized as a layer structure on a common support substrate, particularly a silicon semiconductor crystal. Semiconductor circuits of this type are typically produced in large numbers on a common support (wafer) and then diced. For a functional test before further processing of the integrated semiconductor circuit, one or more integrated connection nodes are provided, which can be supplied with different in-circuit test signals in a test mode and with an operating signal in a normal mode. The test signals can be picked up, for example, with use of an electrically conductive test needle directly from the connection node or they are provided at the connection node for further processing by the integrated semiconductor circuit and, for this purpose, conveyed by one or more traces, connected to the connection node.

To realize the most compact design possible of the semiconductor circuit, it can be provided that a connection node is connected to several signal lines, each of which is assigned a release device. In a release state, switching means of the respective assigned release device have the task of providing an in-circuit signal, particularly a test signal, over the respective signal line to the connection node. In a blocking state, the particular switching means have the task of causing a block of the assigned signal line. In so doing, it is especially important that the release device assures reliable blocking of the signal line irrespective of an electric potential applied to the signal line. This avoids the situation that a test signal coupled in from outside or provided by another signal line to the connection node is coupled into the circuit in an undesired manner over the signal line that is blocked by the release device. The switching means are controlled by control means, which are typically influenced by means of a digital release signal, in order to provide a corresponding switching signal to the switching means.

Each of the in-circuit test signals can be a static or time-variable signal, whose level is the same, higher, or lower than the level of the other test signals. The operating signal applied during normal operation of the integrated semiconductor circuit can be a static or time-variable signal, whose level is the same, higher, or lower than the level of the test signals.

Reference is made hereinbelow FIG. 1 for a more detailed description of a release device known from the conventional art.

### SUMMARY OF THE INVENTION

It is therefore an object of the present invention to provide an integrated semiconductor circuit, which enables an improved determination of in-circuit signals.

This object is attained by an integrated semiconductor circuit, in which the control means are formed in such a way that a cross-current-free release of the specific signal line is assured. A cross current is an electric current that flows proceeding from a test signal terminal, realized in the semiconductor circuit, into the release device and thereby distorts the test signal electric potential measurable at the connection node. This applies particularly when the test signal terminal is a high-impedance terminal, which is not capable of providing a higher electric current. In other words, a cross current in the release device results in a considerable potential difference between the test signal terminal and the connection node or in a potential difference at the test signal terminal itself due to the internal resistance of the test signal source; in this case, this potential difference may cause an undesirably large measuring error. It is possible to avoid cross currents of this type with the release device according to the invention. In fact, leakage currents still flow in the release device due to currently unavoidable physical boundary conditions, but these move in the range of a few nanoamperes and therefore have an effect, lower by a factor of 100 to 1000, on the measuring result than the cross currents, as may occur in release devices according to the prior art.

It is achieved accordingly by a cross-current-free transmission of the test signal to the connection node with use of the release device according to the invention that the test signal provided at the connection node corresponds at least almost totally to the signal provided at the test signal terminal. In other words, the measuring error for the test signal can be reduced considerably by the cross-current-free transmission of the test signal.

An embodiment of the invention provides that the release device is formed free of discrete resistors. Discrete resistors, as they are used in known release devices, require a considerable area in an integrated semiconductor circuit. Avoidance of discrete ohmic resistors helps ensure an advantageous, compact design of the semiconductor circuit.

In another embodiment of the invention, it is provided that the release device has as a switch being two MOS transistors connected anti-series, whose control terminals are clamped to different electric potentials. In this case, an electric potential at the control terminal of the first transistor can correspond to an electric potential at a test signal terminal. An electric potential at the control terminal of the second transistor can correspond to the electric potential of the connection node. Consequently, a clear reference potential and thereby a clear switching state are assured for each of the two transistors.

It is provided in another embodiment of the invention that the release device has at least one level converter as a control, whereby an input of the level converter is provided for coupling a release signal and an output of the level converter is provided to supply a control signal to a control terminal of the switch. With use of the level converter, which is also often called a level shifter, a release signal or input signal having a first electric potential can be converted to a control signal or output signal having a second electric potential. Typically, level converters are used to raise the electric potential of an input signal. The release signal in the integrated semiconductor circuit of the invention can be provided particularly by a digital part as a logic signal with a low signal level. With use of the level converter, the release signal is converted into a control signal with a sufficiently large level to reliably block or release the test signal, applied to the signal line, with use of the switching means. Each transistor of the release device is preferably assigned a level converter.

In another embodiment of the invention, it is provided that a first supply terminal of the first level converter is connected to a first supply terminal of the second level converter. A simple circuit structure can be realized in this way.

Another embodiment of the invention provides that a second supply terminal of the first level converter has an electric potential of a test signal terminal. In this way, the control signal, output by the first level converter to the switch, can be matched to the level of the test signal. Therefore, in a realization of the switch as MOS transistors, a signal level, which is reliably sufficient for controlling the switch, is made available at the control terminal of the MOS transistor.

It is provided in another embodiment of the invention that a second supply terminal of the second level converter has an electric potential of the connection node. The advantage of this type of coupling of the second supply terminal is that the second level converter at an appropriate release signal can provide an electric potential at the control terminal of the second transistor that assures reliable blocking of the second transistor. Therefore, by means of this type of coupling of the second supply terminal of the second level converter, the electric potential of the connection node relative to a reference potential, also applied at the level converter, is used as a control voltage interval for the second transistor. As a result, there is a dynamic adjustment of the control voltage interval to the signal level applied in each case at the connection node.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a circuit diagram for a release device according to the state of the art,

FIG. 2 is a circuit diagram of a level converter for use in the release device of the invention,

FIG. 3 is a circuit diagram of a release device according to the invention,

FIG. 4 is a detail of a circuit diagram of an integrated semiconductor circuit with a connection node and several signal lines provided with release devices.

### DETAILED DESCRIPTION

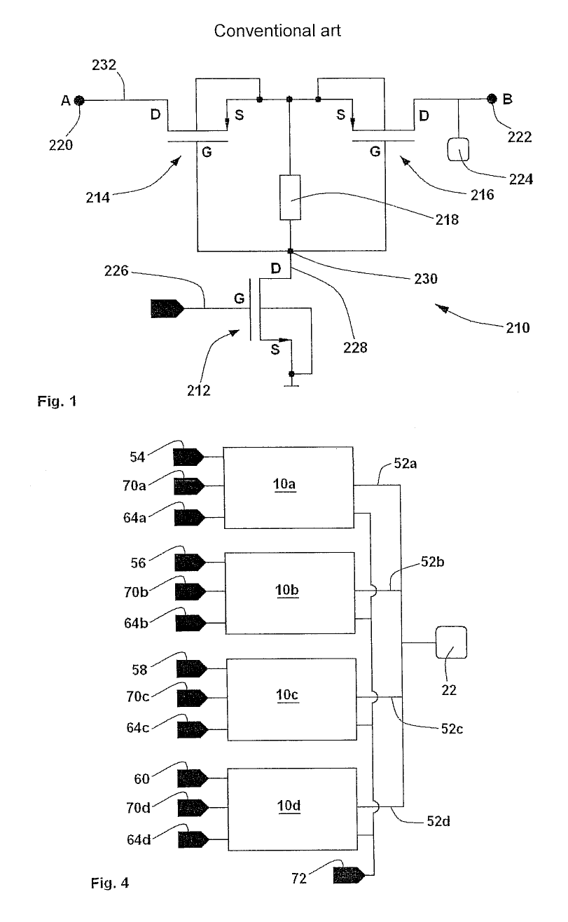

Release device 210, shown in FIG. 1, according to the state of the art is realized in an integrated semiconductor circuit, which is not shown in greater detail. Release device 210 has an NMOS transistor 212, a first PMOS transistor 214, a second PMOS transistor 216, and a resistor 218.

A release signal line 226, which can be supplied with a release signal from a digital part (not shown) of the integrated semiconductor circuit, is connected to a control terminal, designated as gate terminal G, of NMOS transistor 212. The first current terminal, designated as source terminal S, of NMOS transistor 212 is connected to ground, whereas the second current terminal, designated as drain terminal D, of NMOS transistor 212 is connected to a control signal line 228.

Control signal line 228 ends at a control terminal node 230, which is electrically connected to resistor 218 and to the control terminals, designated as gate terminals G, of the first and second PMOS transistors 214, 216. The first current terminals, designated as source terminals S, of the two PMOS transistors 214, 216 are connected to control terminal node 230 via resistor 218, which has an exemplary resistance value of 1 megaohm. The second current terminals, designated as drain terminals D, of the two PMOS transistors 214, 216, like the first current terminals S, are connected to a test signal line 232 formed between electrical nodes 220 and 222. Therefore, the two PMOS transistors 214, 216 are looped in test signal line 232 and can cause blocking or release of test signal line 232. A connection node 224, which is made as a test pad and can be sampled with an electrically conductive test needle (not shown), branches off from test signal line 232.

When a release signal with a logic “low” level is applied at release signal line 226, the control voltage UGS at NMOS transistor 212 is not sufficient for switching through NMOS transistor 212. Therefore, control signal line 228 and control terminals G of the first and second PMOS transistors 214, 216, because of the potential equalization across resistor 218, have the electric potential of the first current terminals S of the first and second PMOS transistors 214, 216. Thereby, no notable control voltage UGS is present between control terminals G and current terminals S of PMOS transistors 214, 216, so that at least the PMOS transistor 214, 216 blocks whose second current terminal D has a lower electric potential compared with control terminals G.

When a release signal with a logic “high” level is applied at release signal line 226, control voltage USG at NMOS transistor 212 rises above the threshold voltage, so that NMOS transistor 212 is switched through. Thereby, control signal line 228 and control terminals G of the first and second PMOS transistors 214, 216 have a ground potential. As a result, a negative control voltage is produced at control terminals G compared with the electric potential applied between nodes 220 and 222, so that both PMOS transistors 214, 216 are switched through. In this state, therefore, there is an electrically conductive connection between nodes 220 and 222.

However, even in a large selected resistor 218, a cross current flows from node 220 or from node 222 to the ground potential. As a result, a considerable measuring error can occur for an electric potential to be measured at node 222, provided node 220 is made as a high-impedance connection.

In the currently conventional design technologies for integrated semiconductor circuits, resistors are realized with resistance values up to a range of about 1 megaohm. Still larger resistors are very disadvantageous both from the technological and economic standpoint. At an exemplary selected resistance value of 1 megaohm for resistor 218 and an exemplary selected test voltage of 5 V at node 220 or 222, in the previously described, known release device 210, a cross current of about 5 μA flows across resistor 218 at the ground terminal. At the test voltages of high-impedance test terminals, this cross current distorts the test result sampled at node 222.

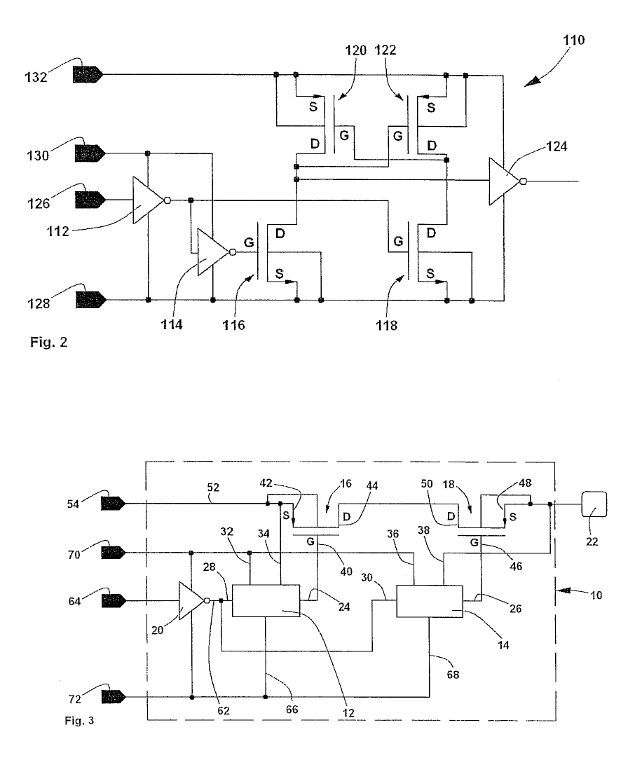

The circuit parts, described in the following FIGS. 2 to 4, are used to reduce cross currents. The embodiment, shown in FIG. 2, of a level converter 110 enables raising of a first signal level of a release signal, which can be applied to a release signal input 126, to a second signal level of the electric potential applied at a second supply terminal 132. This is particularly important when a release signal, which is not generated by a digital circuit (not shown), is to be used to control a likewise not shown circuit part, which is operated at a higher signal level. Typically, the digital circuit can provide only signals with low signal levels.

A logic signal, which is applied at release signal input 126 and can assume a “low” level or a “high” level, is inverted in a first inverter 112. The inverted release signal is provided at a control terminal, designated as gate terminal G, of a second NMOS transistor 118. The inverted release signal, moreover, is again inverted by a second inverter 114 and provided to a control terminal G of the first NMOS transistor 116. Depending on the signal level of the release signal, one of the two PMOS transistors 120, 122 is connected conductively and applies an appropriate electric potential at third inverter 124.

A release signal, provided at release signal input 126 and having a “low” level, causes the first NMOS transistor 116 to block. The second NMOS transistor 118, in contrast, becomes conductive, because a positive control voltage UGS is applied there between control terminal G and the first current terminal S, which is at a lower reference potential, particularly ground. As a result, the reference potential/ground potential is applied at control terminal G of the first PMOS transistor 120 via the assigned connecting line (not described in greater detail) from second current terminal D of the second NMOS transistor 118. As a result, a negative voltage is applied between control terminal G of the first PMOS transistor 120 and the first current terminal of the first PMOS transistor 120. The first PMOS transistor 120 thereupon becomes conductive and provides the supply voltage, applied at the second supply terminal 132, to the second current terminal D of the first NMOS transistor 116, to control terminal G of the second PMOS transistor 122, and to the input of third inverter 124. Third inverter 124 inverts the “high” level applied at its input and provides a “low” level as the output signal.

If in contrast a release signal with a “high” level is applied at release signal input 126, a positive level is applied at the first NMOS transistor 116 via the double inversion of the first and second inverter 112, 114; said NMOS transistor thus becomes conductive or “switches through” and places the second PMOS transistor 122 and the input of the third inverter 124 at the reference potential/ground potential or thus at a “low” level. The second PMOS transistor 122 also switches through and places the control input G of the first PMOS transistor at the potential of the second supply terminal 132, so that it is reliably blocked. Because the reference potential of the reference potential terminal 128 is applied at least substantially at third inverter 124 and this is typically a ground potential, third inverter 124 inverts a logic “low” level to a logic “high” level at the voltage level of the second supply terminal 132. This logic “high” level, which has a higher level than the originally introduced release signal, can now be used as a switching signal for other circuit parts (not shown).

The previously described level converter can also be designed in modified form without a change in its function. An embodiment, which is not shown, is conceivable in which for simplification the second inverter (114) and the third inverter (128) are omitted. Other embodiments of level converters may also be used.

Release device 10, shown in FIG. 3, has a first level converter 12 and a second level converter 14 as control means and a first PMOS transistor 16 and a second PMOS transistor 18 as switching means. Level converters 12 and 14 are, for example, designed according to FIG. 2. The use of the level converters 12, 14 allows, in particular, a control of the PMOS transistors 16, 18 when their potential on their inputs or their outputs lies on the level of their supply voltage. Through the level converters, the control signals are changed from a first, preferably lower potential, to a second, preferably higher potential. Thereby it is possible to control the PMOS-Transistors that are switched with a higher potential. Furthermore, an inverter 20 is provided, which is connected to input terminals 28, 30 of the two level converters 12, 14. A logic input signal or a release signal for inverter 20 is provided by a digital part (not shown in greater detail) of the integrated semiconductor circuit and is used to produce a release or blocking of a signal line 52.

For this purpose, PMOS transistors 16, 18 with their first and second current terminals 42, 44, 48, 50, also designated as source terminals S and as drain terminals D, are looped in signal line 52. The first current terminal 42 of the first PMOS transistor 16 is connected to a test signal terminal 54, at which an electric potential can be applied, which is to be conducted to a connection node 22. The second current terminal 44 of the first PMOS transistor 16 is connected to the second current terminal 50 of the second PMOS transistor 18. Its first current terminal 48 is connected to connection node 22. Control terminals 40, 46, also designated as gate terminals G, of PMOS transistors 16, 18 are each controlled by signal levels, which can be applied to output terminals 24, 26 of level converters 12, 14. These signal levels are controlled by the logic signal levels, applied at input terminals 28, 30 of level converters 12, 14.

The anti-series arrangement of the two PMOS transistors 16, 18 and the assigned level converters 12 and 14 achieve that irrespective of the electric potential, applied between connection node 22 and the first test signal terminal 54, complete blocking or release of signal line 52 can be achieved.

Input terminals 28, 30 of level converters 12, 14 are connected to an output 62 of inverter 20. An input 64 of inverter 20 receives as an input signal a logic release signal from a digital part (not shown in greater detail) of the integrated semiconductor circuit. The release signal has an electric potential, which is typically lower than an electric potential of the test signal applied at the first test signal terminal 54. The specific first supply terminals 32, 36 of level converters 12, 14 are connected to the supply voltage of the digital part. The second supply terminal 34 of the first level converter 12 is connected to test signal terminal 54. The second supply terminal 38 of the second level converter 14 is connected to connection node 22. The mode of action of this specific electrical connection of the second supply terminals 34, 38 is described in greater detail as part of the functional description, provided below, for release device 10.

The levels that become established at relevant nodes in release device 10, when different logic levels are fed in at the release terminal or input 64 of inverter 20, are to be described hereafter.

When an input signal or release signal with a logic “low” level is made available at input 64 of inverter 20, this signal is provided by inverter 20 as a logic “high” signal with the level of the digital part supply voltage, which is provided via a digital part supply terminal 70, applied at both input terminals 28, 30 of the two level converters 12, 14. The two level converters 12, 14, each of which is made according to the embodiment described in FIG. 2, convert the logic “high” signal with the level of the digital part supply voltage into logic “high” signals with the levels of the first test signal terminal 54 or of connection node 22.

In other words, the first level converter 12, whose second supply terminal 34 is connected to the first test signal terminal 54, provides a logic “high” signal at the level of the test signal to control terminal 40 of the first PMOS transistor 16. The second level converter 14, whose second supply terminal 38 is connected to connection node 22, provides a logic “high” signal with the level applied at connection node 22. Depending on the signal applied at connection node 22, this level can be higher or lower than the level of the first test signal terminal 54.

Consequently, a logic “high” signal with the level of the first test signal terminal 54 is applied at control terminal 40 of the first PMOS transistor 16, whereas a logic “high” signal with the level of the signal applied at connection node 22 is provided at control terminal 46 of the second PMOS transistor 18.

Irrespective of the electric potential between the first test signal terminal 54 and connection node 22, it is assured by the voltages applied at control terminals 40, 46 of PMOS transistors 16, 18 that at least one of the two PMOS transistors 16, 18 blocks, because no negative voltage UGS, necessary to release PMOS transistors 16, 18, is present between the respective control terminal and the respective first current terminals.

However, when an input signal or release signal with a logic “high” level is made available at input 64 of inverter 20, this signal is provided by the inverter as a logic “low” signal with the level of the supply voltage of the digital part to the two input terminals 28, 30 of the two level converters 12, 14. The two level converters 12, 14 convert the logic “low” signal with the level of the digital part supply voltage into logic “low” signals with a changed level.

The first level converter 12, whose second supply terminal 34 is connected to the first test signal terminal 54, provides a logic “low” signal in an interval between the level of the test signal and the level of the reference potential, which is applied at reference potential terminal 66, to control terminal 40 of the first PMOS transistor 16. The second level converter 14, whose second supply terminal 38 is connected to connection node 22, provides a logic “low” signal in an interval between the level applied at connection node 22 and the level of reference potential terminal 68. Both reference potential terminals 66, 68 are connected to ground terminal 72.

Thereby, a logic “low” signal is applied both at control terminal 40 of the first PMOS transistor 16 and at the second control terminal 46 of the second PMOS transistor 18. Thus, there is a negative control voltage, necessary for switching through the two PMOS transistors 16, 18, and the two PMOS transistors 16, 18 can release signal line 52. Because apart from the thus far physically unavoidable charge transfers in the nanoampere region, there is no current from connection node 22 or from test signal terminal 54 to level converter 12, 14, release device 10 enables a cross-current-free release of signal line 52. Thereby, a precise measurement of the test signal potential at connection node 22 can also be made at a high-impedance test signal terminal 52.

In the embodiment shown in FIG. 4, several release devices 10a, 10b, 10c, and 10d according to the embodiment of FIG. 3 are connected to a common connection node 22. Each of the release devices 10a, 10b, 10c, 10d is connected to a test signal terminal 54, 56, 58, 60, at which a test signal with a positive or negative or alternating electric potential is applied. All release devices 10a, 10b, 10c, 10d are each controlled by a release signal provided by a digital part not shown in greater detail. Another signal, particularly a signal applied during normal operation of the integrated semiconductor circuit, can also be applied at connection node 22 via the test signals provided by test signal terminals 54, 56, 58, 60. If none of the release devices 10a, 10b, 10c, 10d are controlled by a corresponding release signal, all assigned signal lines 52a, 52b, 52c, 52d are reliably blocked and a signal level applied at connection node 22 is not transmitted further to test signal terminals 54, 56, 58, 60.

The above described example embodiment also allows for the enablement negative supply voltages. Hereto, the PMOS transistors would be replaced with NMOS transistors.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An integrated semiconductor circuit comprising:
a connection node, which is provided for decoupling electric signals;
a plurality of electric signal lines, which are formed to provide in-circuit signals or test signals to the connection node; and
an in-circuit release device, which is switched between a release state to release the signal line and a blocking state to block the signal line, is looped in the signal lines;
wherein the release device includes at least one switch, that is formed in such a way that the blocking state for the signal line is assured irrespective of a signal electric potential applied to the signal line,
wherein the release device includes a control for controlling the switch, and
wherein the control is formed such that a cross-current-free release of the specific signal line is assured.

2. The integrated semiconductor circuit according to claim 1, wherein the release device is formed free of discrete resistors.

3. The integrated semiconductor circuit according to claim 1, wherein the switch is formed of two MOS transistors connected anti-series, whose control terminals are clamped to different electric potentials.

4. The integrated semiconductor circuit according to claim 1, wherein control has at least one level converter, an input of the level converter being provided for coupling a release signal and an output of the level converter being provided to supply a control signal at a control terminal of the switch.

5. The integrated semiconductor circuit according to claim 4, wherein each transistor of the release device is assigned a level converter.

6. The integrated semiconductor circuit according to claim 4, wherein a first supply terminal of the first level converter is connected to a first supply terminal of the second level converter.

7. The integrated semiconductor circuit according to claim 5, wherein a second supply terminal of the first level converter has an electric potential of a test signal terminal.

8. The integrated semiconductor circuit according to claim 1, wherein a second supply terminal of the second level converter has an electric potential of the connection node.
